(19) United States
(12) Patent Application Publication
(10) Pub. No.: US 2024/0085466 A1
(43) Pub. Date: Mar. 14, 2024

(54) POWER CONSUMPTION BEHAVIOR ANALYZING DEVICE AND POWER CONSUMPTION BEHAVIOR ANALYZING METHOD

(71) Applicant: INSTITUTE FOR INFORMATION INDUSTRY, TAIPEI CITY (TW)

(72) Inventors: SU-AN LIU, TAIPEI CITY (TW); KUEI-CHUN CHIANG, TAIPEI CITY (TW); YUNG-CHIEH HUNG, TAIPEI CITY (TW)

(21) Appl. No.: 17/973,488

(22) Filed: Oct. 25, 2022

(30) Foreign Application Priority Data
Sep. 12, 2022 (TW) 111134241

(51) Int. Cl. G01R 22/10; G06F 1/28

(52) U.S. Cl. CPC G01R 22/10; G06F 1/28

(57) ABSTRACT

A power consumption behavior analyzing device and a power consumption behavior analyzing method are provided. The power consumption behavior analyzing method includes: generating, according to power consumption data, power consumption curves of household ends, and extracting feature points; acquiring household data records corresponding to the households, respectively; performing a correlation analysis according to the household data records and the power consumption data of the feature points to find household features corresponding to correlations of the feature points as key features based on a correlation threshold value; clustering, according to the key features, total power consumption data to obtain a plurality of household power consumption characteristic curves and a plurality of power consumption patterns; and calculating similarities respectively between a power consumption curve of a to-be-analyzed household end and the household power consumption characteristic curves, and marking the to-be-analyzed household end as a corresponding power consumption pattern.

### CROSS-REFERENCE TO RELATED PATENT APPLICATION

This application claims the benefit of priority to Taiwan Patent Application No. 111134241, filed on Sep. 12, 2022. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an analysis device and an analysis method, and more particularly to a power consumption behavior analyzing device and a power consumption behavior analyzing method for classifying power consumption behaviors based on load data and household features.

### BACKGROUND OF THE DISCLOSURE

With the popularization of environmental awareness, numerous countries have dedicated themselves to energy saving, carbon reduction, and developing a low-carbon economy. Since users can improve their power usage habits and reduce electricity costs with proper guidance, demand-side management (DSM) has become one of the latest energy-saving trends in Europe and the United States. In order to achieve energy-saving goals, it is necessary to analyze power consumption behaviors and provide clear and appropriate energy-saving solutions for households across the nation.

However, existing power consumption analysis methods only rely on power consumption curves in the determination of power consumption patterns of users, and cannot easily interpret analysis results of the power consumption patterns. Therefore, it is difficult for power consumption analysis of the power consumption behaviors and effective recommendations to be accurately provided for making adjustments to power consumption.

### SUMMARY OF THE DISCLOSURE

In response to the above-referenced technical inadequacies, the present disclosure provides a power consumption behavior analyzing device and a power consumption behavior analyzing method for classifying power consumption behaviors based on load data and household features.

In one aspect, the present disclosure provides a power consumption behavior analyzing method suitable for a power consumption behavior analyzing device that includes a processor and a storage unit, the storage unit stores a plurality of power consumption data records and a plurality of household data records of a plurality of household ends, and the power consumption behavior analyzing method is executed by the processor to at least perform the following steps: generating, according to the plurality of power consumption data records, a plurality of power consumption curves corresponding to the plurality of household ends, respectively, and extracting a plurality of feature points for each of the power consumption curves; acquiring the household data records corresponding to the plurality of household ends, respectively, in which the household data records include a plurality of feature parameter values respectively used to describe a plurality of household features; performing a correlation analysis according to the household data records and the power consumption data records of the feature points, to obtain the household features corresponding to correlations of the feature points according to a correlation threshold value, and to use the obtained household features as key features; clustering, according to the key features, the power consumption data records to obtain a plurality of household power consumption characteristic curves, in which the plurality of household power consumption characteristic curves correspond to a plurality of power consumption patterns, respectively; and calculating similarities respectively between a power consumption curve of a to-be-analyzed household end and the household power consumption characteristic curves, and marking the to-be-analyzed household end as the power consumption pattern corresponding to the household power consumption characteristic curve that has the highest similarity among the calculated similarities.

In another aspect, the present disclosure provides a power consumption behavior analyzing device, which includes a storage unit and a memory. The storage unit is configured to store a plurality of power consumption data records and a plurality of household data records of a plurality of household ends. The processor is configured to perform the following steps: generating, according to the plurality of power consumption data records, a plurality of power consumption curves corresponding to the plurality of household ends, respectively, and extracting a plurality of feature points for each of the power consumption curves; acquiring the household data records corresponding to the plurality of household ends, respectively, in which the household data records include a plurality of feature parameter values respectively used to describe a plurality of household features; performing a correlation analysis according to the household data records and the power consumption data records of the feature points, to obtain the household features corresponding to correlations of the feature points according to a correlation threshold value, and to use the obtained household features as key features; clustering, according to the key features, the power consumption data records to obtain a plurality of household power consumption characteristic curves, in which the plurality of household power consumption characteristic curves correspond to a plurality of power consumption patterns, respectively; and calculating similarities respectively between a power consumption curve of a to-be-analyzed household end and the household power consumption characteristic curves, and marking the to-be-analyzed household end as the power consumption pattern corresponding to the household power consumption characteristic curve that has the highest similarity among the calculated similarities.

Therefore, in the power consumption behavior analyzing device and the power consumption behavior analyzing method provided by the present disclosure, the power consumption behavior under different power consumption patterns can be analyzed to provide customized recommendations for power consumption adjustment, so as to assist users in changing their power consumption behaviors, to encourage the users to participate in demand-side management and to replace home appliances with those that have higher power conversion efficiency, thereby providing sufficient energy-saving incentives for residential users.

Furthermore, in the power consumption behavior analyzing device and the power consumption behavior analyzing method provided by the present disclosure, a considerable quantity of power consumption data records of many power consumers can be analyzed to assist power companies in formulating different electricity tariff plans, such as a plan that is more suitable for a specific composition of family members and lifestyle.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of a power consumption behavior analyzing system according to one embodiment of the present disclosure;

FIG. 2 is a functional block diagram of a power consumption behavior analyzing device according to one embodiment of the present disclosure;

FIG. 3 is a flowchart of a power consumption behavior analyzing method according to one embodiment of the present disclosure;

FIG. 4 shows a schematic diagram showing that a plurality of feature points are found from a power consumption curve according to one embodiment of the present disclosure;

FIGS. 5 to 8 are graphs showing power consumption curves with household features of a night owl type, a peak type, a morning and evening concentrated-early sleep type, and a morning and evening concentrated-late sleep type, respectively, according to one embodiment of the present disclosure;

FIG. 9 is a schematic diagram of a power consumption curve of a to-be-analyzed household end according to one embodiment of the present disclosure; and

FIG. 10 is a schematic diagram showing a calculation of similarities respectively between a power consumption curve of the to-be-analyzed household end and multiple household power consumption characteristic curves in step S15 according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

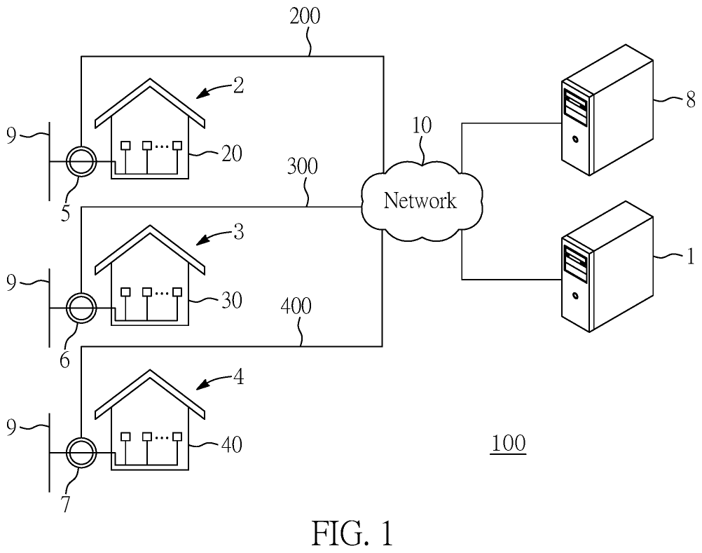

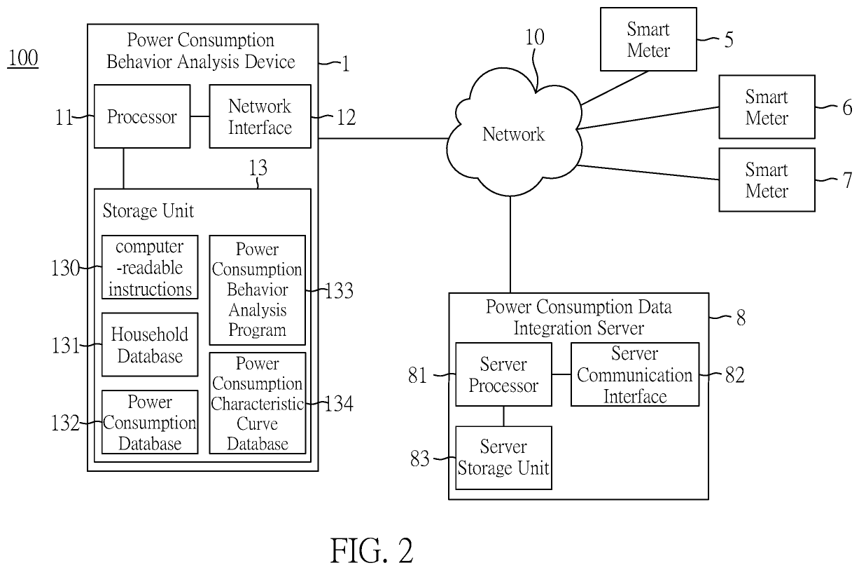

FIG. 1 is a schematic diagram of a power consumption behavior analyzing system according to one embodiment of the present disclosure, and FIG. 2 is a functional block diagram of a power consumption behavior analyzing device according to one embodiment of the present disclosure. Reference is made to FIGS. 1 and 2, one embodiment of the present disclosure provides a power consumption behavior analysis device 1 and a power consumption behavior analysis system 100 including the same. The power consumption behavior analyzing system 100 further includes household ends 2, 3 and 4, smart meters 5, 6, 7, and a power consumption data integration server 8.

The household ends 2, 3, and 4 can respectively include a plurality of electrical appliances disposed in target fields 20, 30, and 40, and the target fields 20, 30, and 40 can be, for example, buildings connected to a utility power 9, and the electrical appliances in the buildings are powered by the utility power 9. The smart meters 5, 6, and 7 can be respectively set between the utility power 9 and the corresponding household ends 2, 3, and 4, and communicate with the power consumption data integration server 8 and the power consumption behavior analyzing device 1 through a network 10. In some embodiments, the network 10 can be, for example, a mobile communication network, the Internet, a local area network, or a combination of the aforementioned various networks, and the present disclosure is not limited thereto.

In some embodiments, the smart meters 5, 6, and 7 can be respectively set between the household ends 2, 3, and 4 and the utility power 9, so as to record total power consumption for the household ends 2, 3, and 4, and transmit power consumption data records 200, 300 and 400 to the power consumption behavior analysis device 1 or the power consumption data integration server 8 in real-time. For example, the power consumption data records 200, 300, and 400 can be firstly transmitted to the electricity consumption data integration server 8 for data integration, and then transmitted to the power consumption behavior analyzing device 1. Alternatively, the power consumption data records 200, 300 and 400 can also be directly transmitted to the power consumption behavior analysis device 1 for data integration, and the present disclosure does not limit objects that the consumption data records 200, 300 and 400 are transmitted to and manners for transmitting the same.

It should be noted that although household ends 2, 3, 4 and smart meters 5, 6, and 7 are shown in FIG. 1, in the power consumption behavior analysis system 100 provided by the present disclosure, the number of household ends is not limited. In addition, in this embodiment, the smart meters 5, 6, and 7 and the power consumption data integration server 8 can belong to power companies, while the power consumption behavior analysis device 1 can belong to a third-party company other than the power companies. Therefore, the power consumption behavior analyzing device 1 can cooperate with the power consumption data integration server 8 to obtain household data records of the household ends 2, 3 and 4 from the power consumption data integration server 8. However, in other embodiments, the power consumption behavior analysis device 1 and the power consumption data integration server 8 can be integrated into a single server. In this case, the power consumption behavior analysis device 1 can directly communicate with the smart meters 5, 6, and 7 through the network 10.

In some embodiments, the smart meters 5, 6, and 7 can have a wired or wireless configuration, and can be installed in power circuits of a switchboard of the utility power 9. The smart meters 5, 6, and 7 can be configured to measure total power consumptions of the household ends 2, 3, and 4 respectively at a predetermined sampling frequency. The generated power consumption data records 200, 300 and 400 are then periodically transmitted to the power consumption behavior analysis device 1 or the power consumption data integration server 8.

Reference is further made to FIG. 2, the power consumption behavior analysis device 1 provided by the present disclosure can include a processor 11, a network interface 12 and a storage unit 13. The network interface 12 and the storage unit 13 are electrically connected to the processor 11, and the network interface 12 can be a wired network interface or a wireless network interface, and can be connected to the power consumption data integration server 8 and the smart meters 5, 6 and 7 through the network 10. The storage unit 13 can be a flash memory, a hard disk or any storage medium with the same function. The storage unit 13 stores a plurality of computer-readable instructions 130, a household database 131, a power consumption database 132, a power consumption behavior analysis program 133 and a power consumption characteristic curve database 134. The household database 131 is used for storing multiple household data records of the household ends 2, 3, and 4, and the power consumption database 132 is used to store multiple power consumption data records from household ends 2, 3, and 4, for example, the power consumption data records 200, 300 and 400 transmitted by smart meters 5, 6, and 7. It should be noted that the power consumption behavior analysis method of the present disclosure mentioned hereinafter can be implemented by configuring the processor 11 to execute the computer-readable instructions 130 or the power consumption behavior analysis program 133 stored in the storage unit 13.

On the other hand, the power consumption data integration server 8 can include a server processor 81, a server communication interface 82 and a server storage unit 83. The server communication interface 82 and the server storage unit 83 are electrically connected to the server processor 81. The server communication interface 82 can also be a wired network interface or a wireless network interface, and can be connected to the power consumption behavior analysis device 1 and smart meters 5, 6 and 7 through the network 10. The server storage unit 83 can also be a flash memory, a hard disk, or any other storage medium with the same function. It should be noted that data stored in the household database 131 and the power consumption database 132 mentioned above can also be firstly obtained by the power consumption data integration server 8, and can be stored in the server storage unit 83. Corresponding data transmission can then be performed according to the communication between the power consumption data integration server 8 and the power consumption behavior analysis device 1.

In detail, in one embodiment of the present disclosure, to further analyze household power consumption behaviors and habits hidden behind power load data, in an analysis process provided by the present disclosure, a composition of family members, a type of residence, possessing state of electrical equipment and other household features are further considered. Therefore, the household data records stored in the above-mentioned household database 131 can include the number and the composition of family members, the type of residence, and the possessing state of electrical equipment. Taking the composition of family members as an example, the corresponding household data records can include age and occupation of all members of the corresponding household end, and more specifically, can include information that indicates whether there are young children (2 to 12 years old), preschool children (under 2 years old) or retirees. The type of residence can be, for example, an elevator building or an apartment and a service life thereof, and the possessing state of electrical equipment can include specifications and usage frequency of all electrical appliances in the corresponding household end.

In addition, one or more of the power consumption data integration server 8 and the electricity consumption behavior analysis device 1 can provide questionnaires through a web interface or a program interface for users of the household ends 2, 3, and 4 to fill in the questionnaires and upload the household data records by themselves. The household data records can be stored in the household database 131 in a form of feature parameter values that are used to describe the corresponding household features.

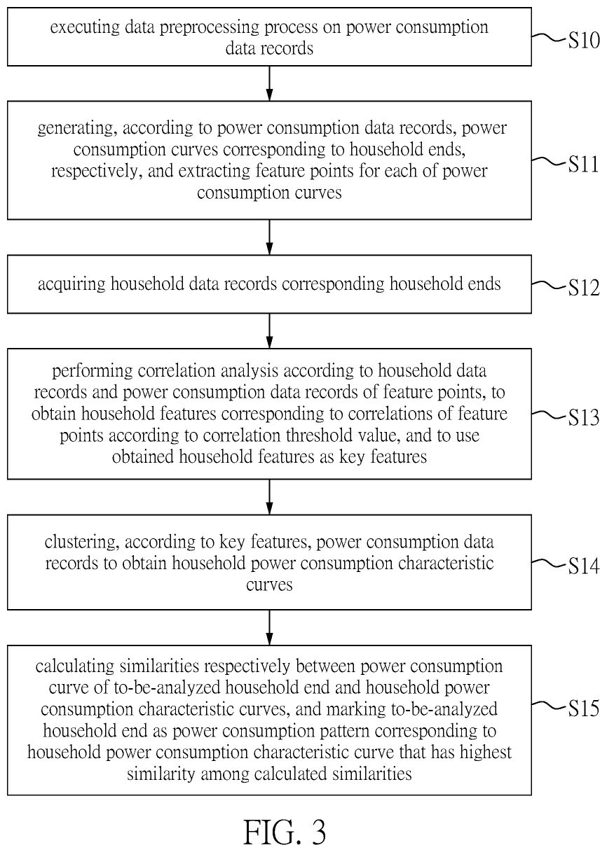

Reference is made to FIG. 3, which is a flowchart of a power consumption behavior analyzing method according to one embodiment of the present disclosure. As shown in FIG. 3, the present disclosure provides a power consumption behavior analyzing method, which is applicable to the foregoing power consumption behavior analyzing system 100 and the power consumption behavior analyzing device 1. Specifically, in the power consumption behavior analyzing method, the processor 11 can be configured to perform the following steps:

Step S10: executing a data preprocessing process on the plurality of power consumption data records.

For example, the data preprocessing process can include one or more of data integration, data cleaning, data resampling, and maximum-minimum normalization. For example, each of the power consumption data records collected over a period of time can be consolidated, and meaningless data (for example, data of a power meter during a power outage) can be removed, and the original data records can be resampled with a re-sampling period of time that is longer than a sampling period of time of the smart meters, and the maximum-minimum normalization is performed by re-scaling the resampled data records into an interval of [0, 1] according to the maximum and minimum values among the resampled data records.

Step S11: generating, according to the plurality of power consumption data records, a plurality of power consumption curves corresponding to the plurality of household ends, respectively, and extracting a plurality of feature points for each of the power consumption curves. Each of the feature points is an extreme point or an inflection point.

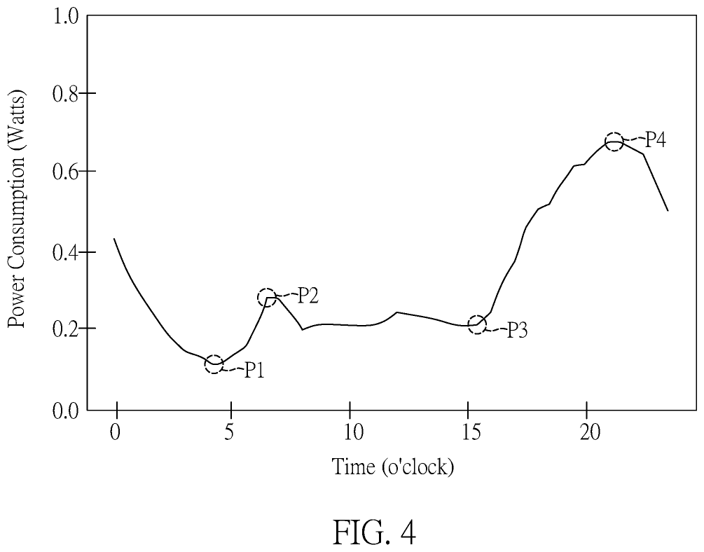

FIG. 4 shows a schematic diagram showing that a plurality of feature points are found from a power consumption curve according to one embodiment of the present disclosure. As shown in FIG. 4, for each of the household ends 2, 3, 4, a fixed period of time is taken as an interval, for example, every 15 minutes or every 30 minutes, the power consumption in each fixed period of time is averaged to represent the power load of that period of time, so as to obtain multiple average values of power consumption respectively corresponding to a plurality of predetermined time points in each day. For example, if the interval is 15 minutes, a total of 96 data points will be obtained in each day, and if the interval is 30 minutes, a total of 48 data points will be obtained in each day. However, the above-mentioned quantity of data points is only one possible example, and is not intended to limit the present disclosure.

Next, the plurality of average values of power consumption can be plotted according to the predetermined time points to obtain the plurality of power consumption curves. For example, the obtained data points can be drawn into a power consumption curve as shown in FIG. 4, and any feature points can be further searched for from the power consumption curve. For example, feature points P1, P2, P3 and P4 can be found from the power consumption curve in FIG. 4, and the feature points P1, P2, P3 and P4 can correspond to times such as 4:30, 6:30, 15:00, and 21:00, respectively. It should be noted that the so-called feature points refer to extreme points or inflection points that appear on the power consumption curve, and when the extreme points or the inflection points appear, it usually means that the power consumption behaviors of the household end are changed. Therefore, the obtained feature points can be used to analyze power consumption patterns of each household end in the subsequent steps.

Step S12: acquiring a plurality of household data records corresponding the plurality of household ends. The household data records include a plurality of feature parameter values that are respectively used to describe a plurality of household features.

As described above, the stored household data records can be retrieved from the above-mentioned household database 131, and the retrieved household data records can include the number and the composition of family members, the type of residence, and the possessing state of electrical equipment. Taking the composition of family members as an example, the corresponding household data records can include age and occupation of all members of the corresponding household end, and more specifically, can include information that indicates whether there are young children (2 to 12 years old), preschool children (under 2 years old) or retirees. The type of residence can be, for example, an elevator building or an apartment and a service life thereof, and the possessing state of electrical equipment can include specifications and usage frequency of all electrical appliances in the corresponding household end. The above-mentioned household features can be parameterized to generate a plurality of feature parameter values, which are stored in the storage unit 13 for access by the processor 11 in step S12.

Step S13: performing a correlation analysis according to the household data records and the power consumption data records of the feature points, to obtain the household features corresponding to correlations of the feature points according to a correlation threshold value, and to use the obtained household features as key features. The correlation threshold is the number of the household features that are most related to each of the feature points.

For example, a correlation matrix can be utilized to find out the household features that are most related to power consumption corresponding to the feature points. After sorting correlations obtained from the correlation matrix, according to a value set by the correlation threshold, several household features with higher ones of the correlations corresponding to the value are extracted. Preferably, the correlation threshold of the number of the household features that are most related to each of the feature points is obtained, which is at least 2. For example, all parameterized household features can be listed in the correlation matrix, and Pearson correlation coefficient formula can be used to calculate the correlation coefficients of each household feature, and the correlation coefficients represent a degree of linear correlation between the household features and the feature points.

For example, as shown in Table I below, after the correlation coefficient (that is, the correlation) is calculated, and in response to the correlation threshold being set to 2, the top two household features with the highest correlation coefficients can be obtained for the feature points P1, P2, P3 and P4.

TABLE I

| Feature points | P1 | P2 | P3 | P4 |
|---|---|---|---|---|
| Time | 4:30 | 6:30 | 15:00 | 21:00 |
| Top two | Retirees: | Number of | Retirees: | Number of |
| household | 0.262701 | family | 0.309350 | family |
| features and their | Number of | members: | Number of | members: |
| correlation | family | 0.337051 | family | 0.285144 |
| coefficients | members: | Preschool | members: | Young |
| | 0.249448 | children: | 0.160631 | children |
| | | 0.234961 | | 0.259199 |

Next, the top two features of all feature points can be combined, and finally four household features can be obtained. These four household features are taken as the key features, namely the retirees, the number of family members, the young children and the preschool children.

Step S14: clustering, according to the key features, the power consumption data records to obtain a plurality of household power consumption characteristic curves. In this step, a plurality of different groups with the same characteristics can be found from the household data records related to the key features and the corresponding power consumption curves, that is, one or more specific groups with the same or similar household data records (related to the key features) can be searched for, and the one or more specific groups also have the same or similar trends in the corresponding power consumption curves. Therefore, these different groups can be divided by common power consumption curves that belong to the groups, respectively, and therefore correspond to different power consumption patterns.

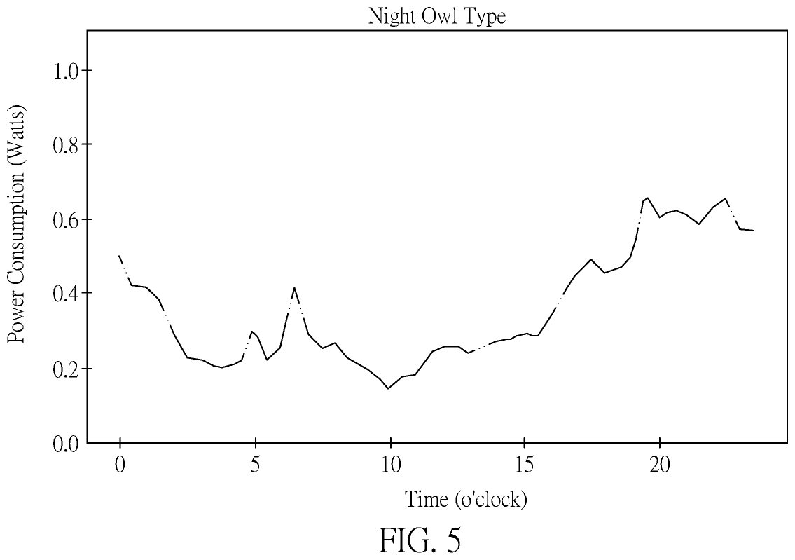

Reference can be made to FIGS. 5 to 8, which are graphs showing household power consumption characteristic curves of a night owl type, a peak type, a morning and evening concentrated-early sleep type, and a morning and evening concentrated-late sleep type, respectively, according to one embodiment of the present disclosure. For example, referring to FIG. 5, when the number of family members in the household end is less than or equals to two and the family members do not include retirees, the household power consumption characteristic curve presented is shown in FIG. 5, the power pattern thereof is the night owl type, which generally refers to the power consumption curves that have power consumption concentrated near night (for example, after 18:00 to 02:00).

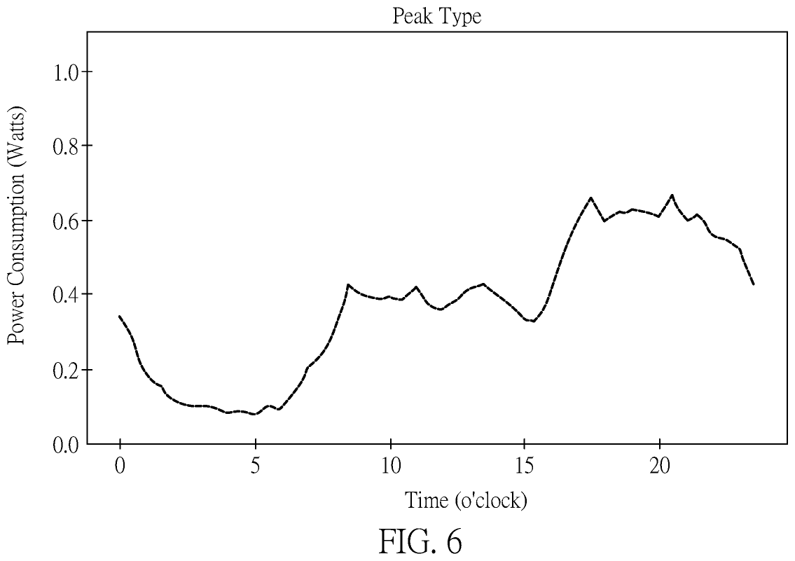

When family members include retirees, the household power consumption characteristic curve presented is shown in FIG. 6, the power consumption pattern thereof is the peak type, which generally refers to the power consumption curves that have a certain degree of power consumption during the day and night (for example, from 07:00 to 1:00).

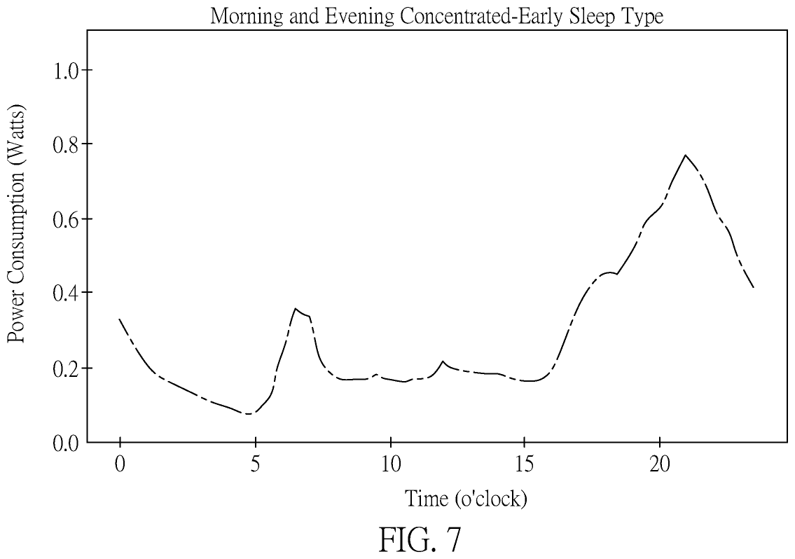

When the family members include young children, since they generally need to sleep early and get up early to meet school schedules, the household power consumption characteristic curve presented is shown in FIG. 7, the power consumption pattern thereof is the morning and evening concentrated-early sleep type, which generally refers to the power consumption curves that have a significant drop after reaching a peak at a certain time in the evening (for example, 21:00), and have a small power consumption spike in the morning (for example, 6:00).

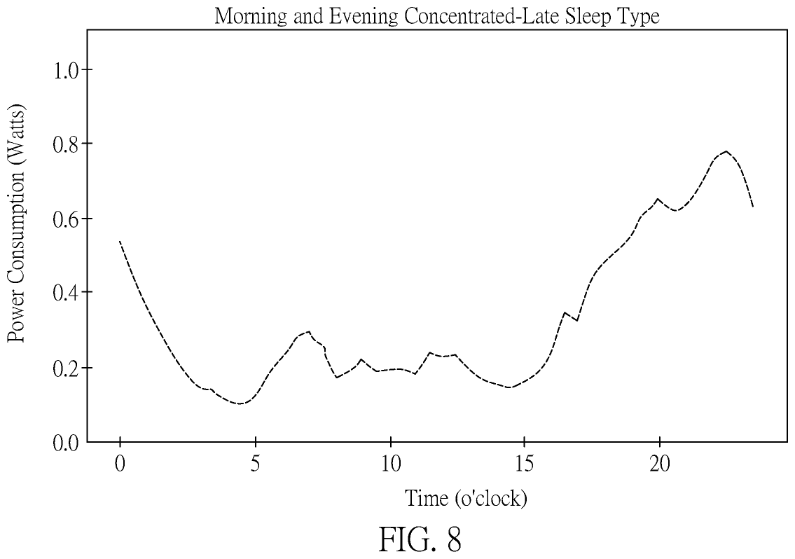

When the family members include preschool children, since the sleep time of the preschool children is less constant, the household power consumption characteristic curve presented is shown in FIG. 8, the power consumption pattern thereof is the morning and evening concentrated-early sleep type, which generally refers to the power consumption curves that have a peak in the evening (for example, after 20:00), but slowly decrease around 23:00, and then produce a small power consumption spike in the morning (for example, 7:00).

Therefore, the household power consumption characteristic curves corresponding to the above four power consumption patterns can be stored in the power consumption characteristic curve database 134 of the storage unit 13, and can be used to analyze a household power consumption curve to be analyzed in the subsequent steps, so as to summarize and find out the power consumption pattern thereof. However, the above-mentioned four power consumption patterns are only one possible embodiment, and are not intended to limit the present disclosure.

Step S15: calculating similarities respectively between a power consumption curve of a to-be-analyzed household end and the household power consumption characteristic curves, and marking the to-be-analyzed household end as the power consumption pattern corresponding to the household power consumption characteristic curve that has the highest similarity among the calculated similarities.

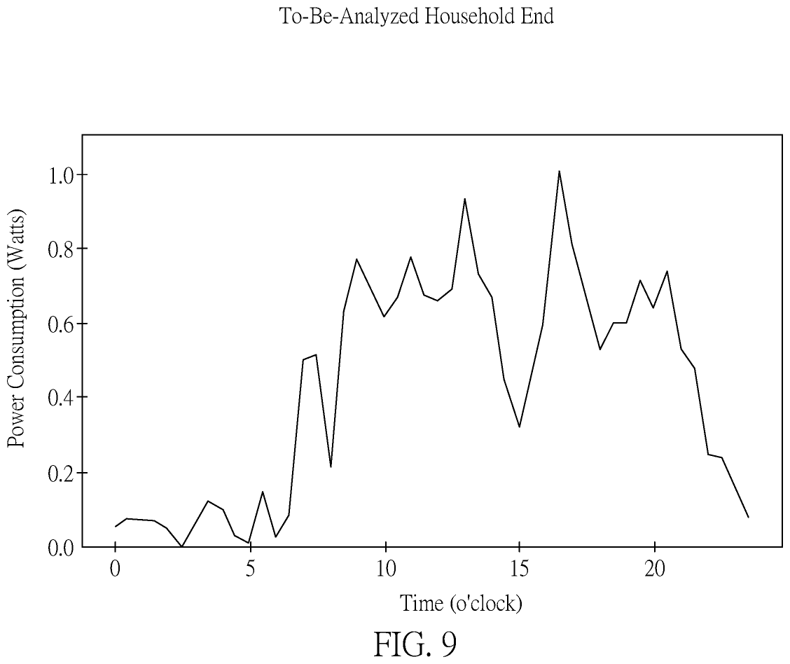

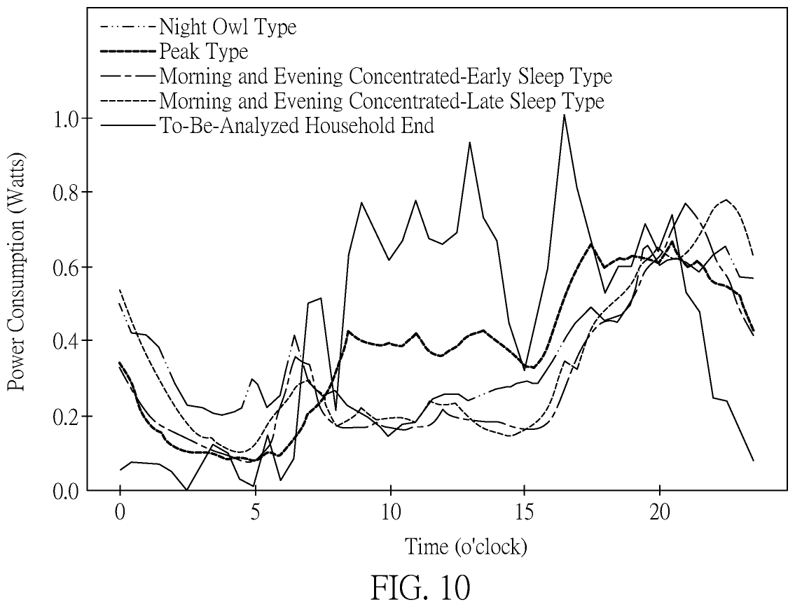

Reference is made to FIGS. 9 and 10, FIG. 9 is a schematic diagram of a power consumption curve of a to-be-analyzed household end according to one embodiment of the present disclosure, and FIG. 10 is a schematic diagram showing a calculation of similarities respectively between a power consumption curve of the to-be-analyzed household end and multiple household power consumption characteristic curves in step S15 according to one embodiment of the present disclosure.

In this step, a procedure similar to step S10 can be utilized. After obtaining power consumption data records of the to-be-analyzed household end, preprocessing can be performed, and the power consumption in each fixed period of time is averaged to represent the power load of that period of time, so as to obtain multiple average values of power consumption respectively corresponding to a plurality of predetermined time points in each day. Afterward, the obtained average values of the power consumption are plotted as a power consumption curve, as shown in FIG. 9.

Next, similarities respectively between the power consumption curve of the to-be-analyzed household end and the household power consumption characteristic curves can be calculated. As shown in FIG. 9, since the power consumption curves are plotted together, it can be clearly observed that the power consumption curve of the to-be-analyzed household end is the most similar to the peak type of FIG. 5, and thus the to-be-analyzed household end can be marked as the peak type of power consumption pattern.

Although a comparison result of similarities can be obtained by visual inspection in FIG. 9, in step S15, a plurality of Euclidean distances respectively between the power consumption curve of the to-be-analyzed household end and the household power consumption characteristic curves can be calculated, and the household power consumption characteristic curve corresponding to the shortest one of Euclidean distances can be taken as one having the highest similarity with the power consumption curve of the to-be-analyzed household end.

### Beneficial Effects of the Embodiments

In conclusion, in the power consumption behavior analyzing device and the power consumption behavior analyzing method provided by the present disclosure, the power consumption behavior under different power consumption patterns can be analyzed to provide customized recommendations for power consumption adjustment, so as to assist users in changing their power consumption behaviors, to encourage the users to participate in demand-side management, and to replace home appliances with those having higher power conversion efficiency, thereby providing sufficient energy-saving incentives for residential users.

Furthermore, in the power consumption behavior analyzing device and the power consumption behavior analyzing method provided by the present disclosure, a considerable quantity of power consumption data records of many power consumers can be analyzed to assist power companies in formulating different electricity tariff plans, such as a plan that is more suitable for a specific composition of family members and lifestyle.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power consumption behavior analyzing method suitable for a power consumption behavior analyzing device that includes a processor and a storage unit, wherein the storage unit stores a plurality of power consumption data records and a plurality of household data records of a plurality of household ends, and the power consumption behavior analyzing method is executed by the processor to at least perform the following steps:
generating, according to the plurality of power consumption data records, a plurality of power consumption curves corresponding to the plurality of household ends, respectively, and extracting a plurality of feature points for each of the power consumption curves, wherein each of the feature points is an extreme point or an inflection point;
acquiring the household data records corresponding to the plurality of household ends, respectively, wherein the household data records include a plurality of feature parameter values respectively used to describe a plurality of household features;
performing a correlation analysis according to the household data records and the power consumption data records of the feature points, to obtain the household features corresponding to correlations of the feature points according to a correlation threshold value, and to use the obtained household features as key features;
clustering, according to the key features, the power consumption data records to obtain a plurality of household power consumption characteristic curves, wherein the plurality of household power consumption characteristic curves correspond to a plurality of power consumption patterns, respectively; and
calculating similarities respectively between a power consumption curve of a to-be-analyzed household end and the household power consumption characteristic curves, and marking the to-be-analyzed household end as the power consumption pattern corresponding to the household power consumption characteristic curve that has the highest similarity among the calculated similarities.

2. The method according to claim 1, further comprising: executing a data preprocessing process on the plurality of power consumption data records.

3. The method according to claim 2, wherein the data preprocessing process includes one or more of data integration, data cleaning, data resampling, and maximum-minimum normalization.

4. The method according to claim 1, wherein the step of generating the power consumption curves according to the power consumption data records includes:
for each of the household ends, taking a fixed period of time as an interval, and averaging power consumption in each fixed period of time, so as to obtain a plurality of average values of power consumption respectively corresponding to a plurality of predetermined time points in each day; and
plotting the plurality of average values of power consumption according to the predetermined time points to obtain the plurality of power consumption curves.

5. The method according to claim 1, wherein the household features include a number and a composition of family members, a type of residence, and state of possession of electrical equipment.

6. The method according to claim 1, wherein the step of performing the correlation analysis includes:
using a correlation matrix to find the household features that are most relevant to power consumption corresponding to the feature points.

7. The method according to claim 1, wherein a quantity of the household features that are most relevant to each of the feature points corresponds to the correlation threshold value, and the correlation threshold value is at least 2.

8. The method according to claim 1, wherein the step of calculating the similarities respectively between the power consumption curve of the to-be-analyzed household end and the household power consumption characteristic curves includes:
calculating Euclidean distances respectively between the power consumption curve of the to-be-analyzed household end and the household power consumption characteristic curves, and taking the household power consumption characteristic curve corresponding to a shortest one of Euclidean distances as one having the highest similarity to the power consumption curve of the to-be-analyzed household end.

9. A power consumption behavior analyzing device, comprising:
a processor; and
a storage unit configured to store a plurality of power consumption data records and a plurality of household data records of a plurality of household ends,
wherein the processor is configured to perform the following steps:
generating, according to the plurality of power consumption data records, a plurality of power consumption curves corresponding to the plurality of household ends, respectively, and extracting a plurality of feature points for each of the power consumption curves, wherein each of the feature points is an extreme point or an inflection point;
acquiring the household data records corresponding to the plurality of household ends, respectively, wherein the household data records include a plurality of feature parameter values respectively used to describe a plurality of household features;
performing a correlation analysis according to the household data records and the power consumption data records of the feature points, to obtain the household features corresponding to correlations of the feature points according to a correlation threshold value, and to use the obtained household features as key features;
clustering, according to the key features, the power consumption data records to obtain a plurality of household power consumption characteristic curves, wherein the plurality of household power consumption characteristic curves correspond to a plurality of power consumption patterns, respectively; and
calculating similarities respectively between a power consumption curve of a to-be-analyzed household end and the household power consumption characteristic curves, and marking the to-be-analyzed household end as the power consumption pattern corresponding to the household power consumption characteristic curve that has the highest similarity among the calculated similarities.

10. The device according to claim 9, wherein the processor is configured to execute a data preprocessing process on the plurality of power consumption data records.

11. The device according to claim 10, wherein the data preprocessing process includes one or more of data integration, data cleaning, data resampling, and maximum-minimum normalization.

12. The device according to claim 9, wherein the step of generating the power consumption curves according to the power consumption data records includes:
for each of the household ends, taking a fixed period of time as an interval, and averaging power consumption in each fixed period of time, so as to obtain a plurality of average values of power consumption respectively corresponding to a plurality of predetermined time points in each day; and
plotting the plurality of average values of power consumption according to the predetermined time points to obtain the plurality of power consumption curves.

13. The device according to claim 9, wherein the household features include a number and a composition of family members, a type of residence, and state of possessing of electrical equipment.

14. The device according to claim 9, wherein the step of performing the correlation analysis includes:
using a correlation matrix to find out the household features that are most relevant to power consumption corresponding to the feature points.

15. The device according to claim 14, wherein a quantity of the household features that are most relevant to each of the feature points corresponds to the correlation threshold value, and the correlation threshold value is at least 2.

16. The device according to claim 9, wherein the step of calculating the similarities respectively between the power consumption curve of the to-be-analyzed household end and the household power consumption characteristic curves includes:
calculating Euclidean distances respectively between the power consumption curve of the to-be-analyzed household end and the household power consumption characteristic curves, and taking the household power consumption characteristic curve corresponding to a shortest one of Euclidean distances as one having the highest similarity to the power consumption curve of the to-be-analyzed household end.
